(19) United States
(12) Patent Application Publication
(10) Pub. No.: US 2017/0047901 A1
(43) Pub. Date: Feb. 16, 2017

(54) PROTECTION CIRCUIT FOR POWER AMPLIFIER

(71) Applicant: Avago Technologies General IP (Singapore) Pte. Ltd., Singapore (SG)

(72) Inventors: Kyung Min Kim, Gyeonggi-do (KR); Joo Young Jeon, Gyeonggi-do (KR); Joo Min Jung, Seoul (KR); Jung Hyun Kim, Gyeonggi-do (KR)

(21) Appl. No.: 14/824,830

(22) Filed: Aug. 12, 2015

(51) Int. Cl. H03F 1/52; H03F 3/19; H03F 3/21; H03F 1/56

(52) U.S. Cl. CPC H03F 1/52; H03F 1/56; H03F 3/19; H03F 3/21; H03F 2200/451; H03F 2200/555

(57) ABSTRACT

A radio frequency device includes a radio frequency (RF) power amplifier (PA) circuit including a driver stage configured to amplify an input signal to generate an output signal and a power stage configured to amplify the output signal, a first bias circuit configured to supply a first bias current to the driver stage, a second bias circuit configured to supply a second bias current to the power stage, and a protection circuit configured to limit a current flowing in the RF PA. The protection circuit is coupled between the first bias circuit and the second bias circuit.

### BACKGROUND

A Radio Frequency (RF) Power Amplifier (PA) of a wireless communication device is typically designed to be matched into a 50-ohm load impedance and to ensure effective power transmission from an RF input signal to an amplified RF output signal. However, the RF PA is often exposed to load impedance mismatch conditions, undermining the performance thereof. Particularly, a low impedance mismatch may cause an overcurrent to flow in the RF PA, which may damage the RF PA permanently.

What is needed, therefore, is a device that is capable of preventing an overcurrent flow in the RF PA even under low impedance mismatch conditions.

### BRIEF DESCRIPTION OF THE DRAWINGS

The representative embodiments provided herein may be best understood when read with the accompanying drawings. It should be noted that various features depicted therein are not necessarily drawn to scale, for sake of clarity and discussion. Wherever applicable and practical, like reference numerals refer to like elements.

FIG. 1 is a block diagram of a radio frequency device in accordance with a representative embodiment;

FIG. 2 is a schematic of the radio frequency device shown in FIG. 1 comprising a protection circuit in accordance with a representative embodiment;

FIG. 3 illustrates a graphical comparison of a current flowing in a RF PA with the protection circuit and a current flowing in a RF PA without the protection circuit;

FIG. 4 illustrates a modified example of the protection circuit shown in FIG. 2;

FIG. 5 is a detailed schematic of a radio frequency device comprising a protection circuit in accordance with another representative embodiment; and

FIG. 6 illustrates a modified example of the protection circuit shown in FIG. 5.

### DETAILED DESCRIPTION

In the following detailed description, for purposes of explanation but not limitation, representative embodiments disclosing specific details are set forth in order to facilitate a better understanding of the present teachings. However, it will be apparent to one having ordinary skill in the art having had the benefit of the present disclosure that other representative embodiments in accordance with the present teachings that depart from the specific details disclosed herein may still remain within the scope of the appended claims. Moreover, descriptions of well-known apparatuses and methods may be omitted so as to not obscure the description of the representative embodiments.

It is to be understood that the terminology used herein is for purposes of describing particular representative embodiments only, and is not intended to be limiting. Any defined terms are in addition to the technical and scientific meanings of the defined terms as commonly understood and accepted in the technical field of the present teachings.

As used in the specification and appended claims, the terms “a,” “an” and “the” include both singular and plural referents, unless the context clearly dictates otherwise. Thus, for example, “a device” includes one device and plural devices.

Although the terms “first,” “second,” etc. may be used herein to describe various elements, these elements should not be limited by these terms. These terms are used to distinguish one element from another. For example, a first element could be termed a second element, and, similarly, a second element could be termed a first element, without departing from the scope of the present teachings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Hereinafter, radio frequency devices in accordance with the present disclosure are explained with reference to corresponding drawings.

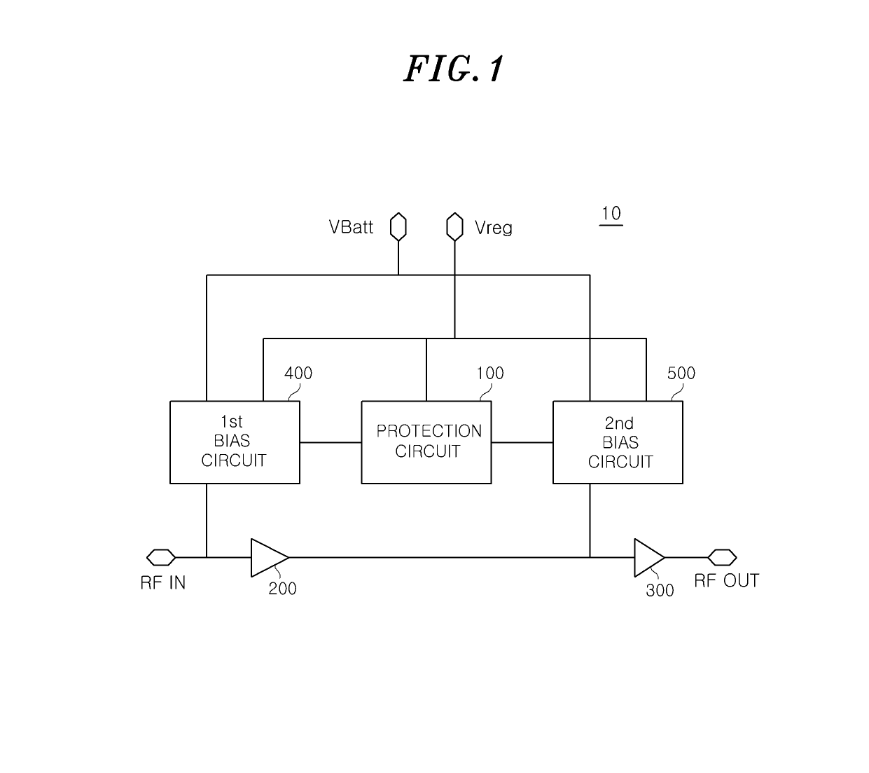

FIG. 1 is a block diagram of a radio frequency device 10 in accordance with a representative embodiment.

The radio frequency device 10 of FIG. 1 comprises a radio frequency power amplifier (RF PA) and a protection circuit 100. The radio frequency power amplifier comprises a driver stage 200, a power stage 300, a first bias circuit 400, and a second bias circuit 500. The protection circuit 100 is supplied with a voltage from a regulated voltage (Vreg), and the first bias circuit 400 and the second bias circuit 500 are supplied with voltages from the regulated voltage (Vreg) and a battery voltage (VBatt). The radio frequency device 10 may be integrated into a single circuit.

The driver stage 200 and the power stage 300 constitute a radio frequency power amplifier circuit, and the present representative embodiment describes the case in which the radio frequency power amplifier circuit has two stages, but the number of the stages is not limited to this and may be two or more.

An input signal, input through an input ten Anal RF IN, is amplified in the driver stage 200, and the output signal of the driver stage 200 is additionally amplified in the power stage 300 and output to an output terminal RF OUT. The first bias circuit 400 supplies a first bias current to the driver stage 200, and the second bias circuit 500 supplies a second bias current to the power stage 300.

Unlike the case of 50-ohm load impedance match and the case of high impedance mismatch, under low impedance mismatch conditions, an overcurrent flows in the first bias circuit 400 and/or the second bias circuit 500. When an overcurrent flows in the first bias circuit 400 and/or the second bias circuit 500, the overcurrent flows also in the radio frequency power amplifier circuit (namely, the driver stage 200 and the power stage 300) and it may damage transistors and elements constituting the radio frequency power amplifier circuit Therefore, the radio frequency device 10 of the present representative embodiment comprises the protection circuit 100 for limiting a current flowing in the radio frequency power amplifier circuit.

This protection circuit 100 is not directly coupled to the driver stage 200 and the power stage 300, and is coupled between the first bias circuit 400 and the second bias circuit 500. Because the protection circuit 100 of the present representative embodiment is not directly coupled to the driver stage 200 and the power stage 300, the protection circuit 100 does not degrade the RF PA performance on a 50-ohm load, unlike the case in which the protection circuit is directly coupled to the driver stage and the power stage.

Meanwhile, the first bias circuit 400, the second bias circuit 500, and the protection circuit 100 may be understood to constitute a single bias device.

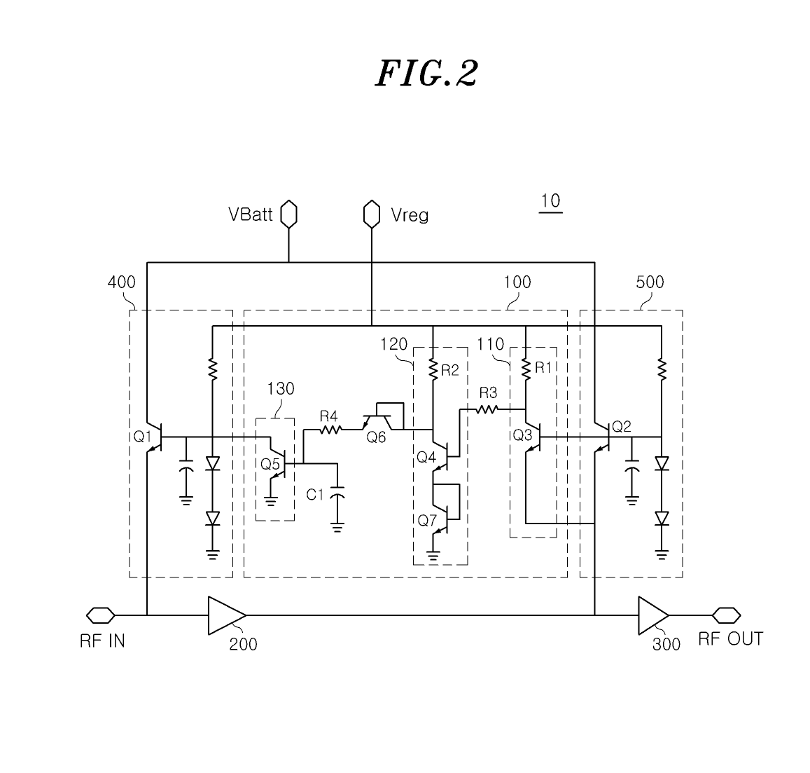

FIG. 2 is a detailed schematic of the radio frequency device 10 comprising the protection circuit 100.

Technical descriptions provided with reference to FIG. 1 may be applicable hereto, and thus repeated descriptions may be omitted here for brevity.

The protection circuit 100 of the radio frequency device 10 comprises a detection circuit 110 and a feedback circuit 130. The detection circuit 110 detects a second bias current flowing in the second bias circuit 500. When the current detected by the detection circuit 110 is equal to or greater than a predetermined threshold current value, the feedback circuit 130 is activated and limits the first bias current flowing in the first bias circuit 400.

Meanwhile, the protection circuit 100 may further comprise an inverting circuit 120. The inverting circuit 120 is coupled between the detection circuit 110 and the feedback circuit 130. The inverting circuit 120 inverts the output of the detection circuit 110, and supplies it as the input to the feedback circuit 130.

As illustrated in FIG. 2, the first bias circuit 400 comprises a first transistor Q1, and the second bias circuit 500 comprises a second transistor Q2. The collector of the first transistor Q1 is coupled to the battery voltage VBatt, and the emitter of the first transistor Q1 is coupled to the input terminal of a driver stage 200. Accordingly, the emitter current of the first transistor Q1 is supplied as a first bias current to the driver stage 200. The collector of the second transistor Q2 is coupled to the battery voltage VBatt, and the emitter of the second transistor Q2 is coupled to the input terminal of a power stage 300. Accordingly, the emitter current of the second transistor Q2 is supplied as a second bias current to the power stage 300.

Meanwhile, the detection circuit 110 comprises a third transistor Q3, which operates as a current mirror circuit of the second transistor Q2, and a first detection resistor R1 for detecting a voltage at the collector of the third transistor Q3. The base of the third transistor Q3 is coupled to the base of the second transistor Q2, and the emitter of the third transistor Q3 is coupled to the emitter of the second transistor Q2. Also, the first detection resistor R1 is disposed between the regulated voltage Vreg and the collector of the third transistor Q3. The device size of the third transistor Q3 is smaller than the device size of the second transistor Q2.

The inverting circuit 120 comprises a fourth transistor Q4 and a second detection resistor R2 for detecting a voltage at the collector of the fourth transistor Q4. The base of the fourth transistor Q4 is coupled to the collector of the third transistor Q3, and the second detection resistor R2 is disposed between the regulated voltage Vreg and the collector of the fourth transistor Q4. The emitter of the fourth transistor Q4 may be coupled to ground directly, or an additional transistor Q7 may be coupled between the emitter of the fourth transistor Q4 and ground. As the base and the collector of the additional transistor Q7 are connected to each other, it may be operated as a diode-connected transistor.

The feedback circuit 130 comprises a fifth transistor Q5. The base of the fifth transistor Q5 is coupled to the collector of the fourth transistor Q4, the collector of the fifth transistor Q5 is coupled to the base of the first transistor Q1, and the emitter of the fifth transistor Q5 may be coupled to ground. Meanwhile, the base of the fifth transistor Q5 may be coupled to ground via a capacitor C1.

Additionally, the protection circuit 100 may further comprise a voltage level shifter, and the voltage level shifter may comprise a first shift resistor R3, a second shift resistor R4, and a sixth transistor Q6. The first shift resistor R3 is disposed between the collector of the third transistor Q3 and the base of the fourth transistor Q4. Also, the second shift resistor R4 and the sixth transistor Q6 are connected in serial, and may be coupled between the collector of the fourth transistor Q4 and the base of the fifth transistor Q5. The voltage level shifter shifts a voltage input to the feedback circuit 130.

Hereinafter, the operation of the protection circuit 100 illustrated in FIG. 2 is described in detail. Under low impedance mismatch conditions, an overcurrent flows in the first bias circuit 400 and/or the second bias circuit 500. When a current flowing in the second bias circuit 500 increases, a current flowing in the third transistor Q3, which operates as the current mirror circuit of the second transistor Q2, also increases. As a result, the detection circuit 110 including the third transistor Q3 may detect sudden increase in the current flowing in the second bias circuit 500. Meanwhile, due to the increase in the current flowing in the third transistor Q3, a current flowing in the first detection resistor R1 also increases, and thus a voltage across the first detection resistor R1 increases. Accordingly, a voltage level at the collector of the third transistor Q3 decreases.

On the other hand, when the voltage level at the collector of the third transistor Q3 decreases, a current flowing in the fourth transistor Q4 also decreases since the collector of the third transistor Q3 is coupled to the base of the fourth transistor Q4. As a result, a current flowing in the second detection resistor R2 also decreases, and thus a voltage across the second detection resistor R2 decreases. Accordingly, a voltage level at the collector of the fourth transistor Q4 increases. Namely, the inverting circuit 120 including the fourth transistor Q4 inverts the input and outputs the inverted input.

When the voltage level at the collector of the fourth transistor Q4 increases, because the collector of the fourth transistor Q4 is coupled to the base of the fifth transistor Q5, the fifth transistor Q5 is activated. When the fifth transistor Q5 is activated, a current to be supplied to the driver stage 200 via the first transistor Q1 flows to ground via the fifth transistor Q5. Therefore, the first bias current of the first bias circuit 400 is limited. As an example, when the current flowing in the first detection resistor R1 of the detection circuit 110 is equal to or greater than a predetermined threshold current value, the feedback circuit 130 including the fifth transistor Q5 is activated, thus enabling limiting the first bias current of the first bias circuit 400.

When the first bias current is limited, a current flowing in the driver stage 200 and the power stage 300 is limited, thus the damage to the transistors and elements, which constitute the driver stage 200 and the power stage 300, may be prevented.

Because the protection circuit 100 of the present representative embodiment may be simply implemented without complicated elements, it is possible to reduce costs and to provide a small sized radio frequency device.

Also, as described above, the protection circuit 100 of the present representative embodiment is coupled between the first bias circuit 400 of the driver stage 200 and the second bias circuit 500 of the power stage 300, rather than directly coupled to the driver stage 200 and the power stage 300. Therefore, unlike the case in which the protection circuit is directly coupled to the driver stage 200 and the power stage 300, the protection circuit does not degrade the radio frequency power amplifier performance on a 50-ohm load.

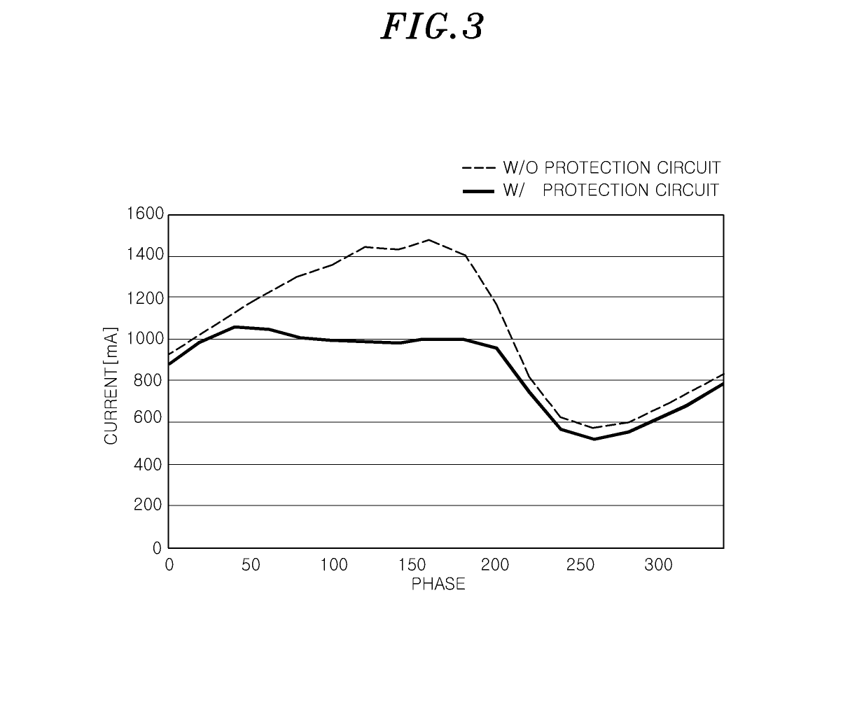

FIG. 3 illustrates currents flowing in the radio frequency power amplifier, comparing the case in which the protection circuit 100 in accordance with the representative embodiment is included and the case in which the protection circuit is not included.

In FIG. 3, the graph illustrates a collector current of the radio frequency power amplifier versus phase at a Voltage Standing Wave Ratio (VISOR) of 10:1. The collector current of the radio frequency power amplifier with the protection circuit 100 is illustrated as a solid line, and the collector current of the radio frequency power amplifier without the protection circuit is illustrated as a dotted line.

As illustrated in FIG. 3, when the protection circuit 100 is coupled to the radio frequency power amplifier, the collector current is limited. In a representative embodiment, the level of the collector current may be limited not to exceed about 1000 mA. This limitation level may be adjusted by adjusting resistance values of the first detection resistor R1 and the second detection resistor R2. Also, the limitation level may be adjusted by adjusting the resistance values of the first shift resistor R3 and the second shift resistor R4. The limitation level is more sensitive to the adjustment of the resistance values of the first detection resistor R1 and the second detection resistor R2, compared to the adjustment of the resistance values of the first shift resistor R3 and the second shift resistor R4.

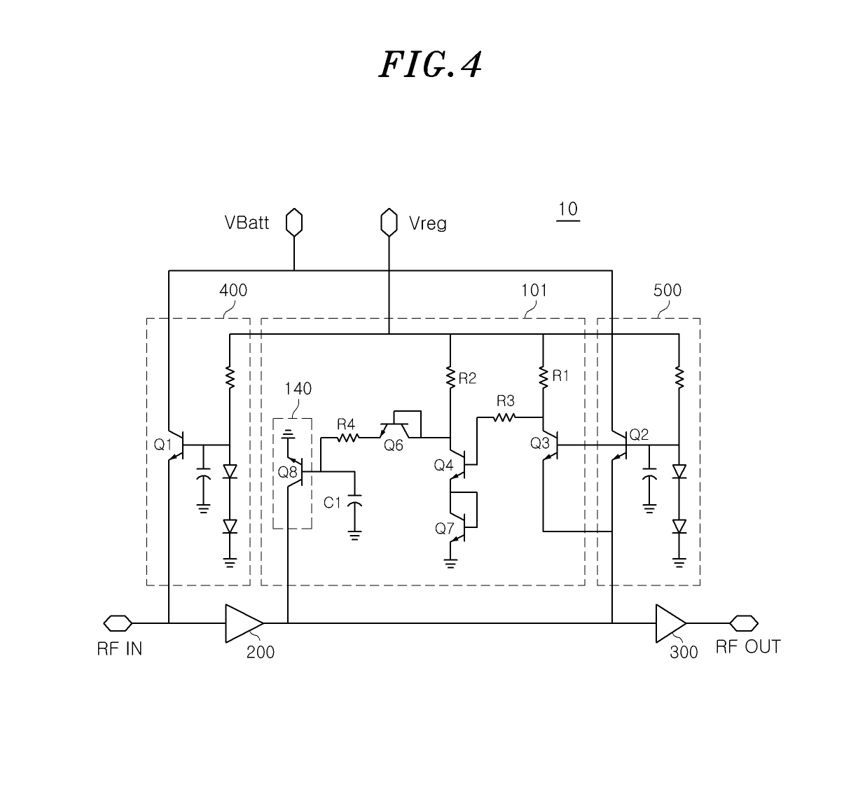

FIG. 4 illustrates a modified example of the protection circuit 100 shown in FIG. 2.

Technical descriptions provided with reference to FIG. 2 may be applicable hereto, and thus repeated descriptions may be omitted here for brevity. Excluding a feedback circuit 140, the configuration of a protection circuit 101 of FIG. 4 is the same as the configuration of the protection circuit 100 of FIG. 2.

The feedback circuit 140 of the protection circuit 101 of FIG. 4 comprises an eighth transistor Q8. The base of the eighth transistor Q8 is coupled to the collector of the fourth transistor Q4, the collector of the eighth transistor Q8 is coupled to the output of the driver stage 200 (i.e., the input of the power stage 300), and the emitter of the eighth transistor Q8 is coupled to ground. Meanwhile, the base of the eighth transistor Q8 may be coupled to ground via a capacitor C1.

Hereinafter, the operation of the feedback circuit 140 illustrated in FIG. 4 is described in detail. As described above with reference to FIG. 2, under low impedance mismatch conditions, an overcurrent flows in the first bias circuit 400 and/or the second bias circuit 500, thus a voltage level at the collector of the fourth transistor Q4 increases. When the voltage level at the collector of the fourth transistor Q4 increases, because the collector of the fourth transistor Q4 is coupled to the base of the eighth transistor Q8, the eighth transistor Q8 is activated. Meanwhile, when the eighth transistor Q8 is activated, impedance seen at the output terminal of the driver stage 200 is changed. Accordingly, using this change, the current flowing in the radio frequency power amplifier circuit may be limited.

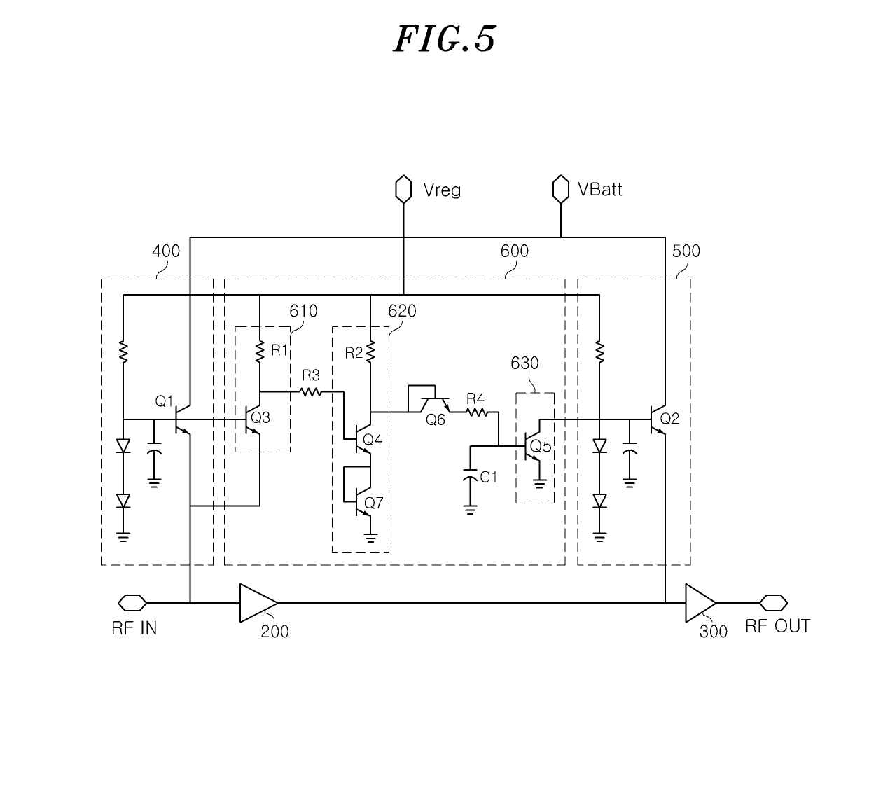

FIG. 5 is a detailed schematic of a radio frequency device including a protection circuit 600 in accordance with another representative embodiment.

Technical descriptions provided with reference to FIG. 2 may be applicable hereto, and thus repeated descriptions may be omitted here for brevity. The radio frequency devices of FIGS. 2 and 5 comprise the same driver stage 200, power stage 300, first bias circuit 400, and second bias circuit 500.

The protection circuit 600 of FIG. 5 comprises a detection circuit 610 and a feedback circuit 630. Unlike the detection circuit 110 of FIG. 2, the detection circuit 610 of FIG. 5 detects a first bias current flowing in the first bias circuit 400. When the current detected by the detection circuit 610 is equal to or greater than a predetermined threshold current value, the feedback circuit 630 is activated and limits a second bias current flowing in the second bias circuit 500.

Meanwhile, the protection circuit 600 may further comprise an inverting circuit 620. The inverting circuit 620 is coupled between the detection circuit 610 and the feedback circuit 630, and inverts the output of the detection circuit 610 and supplies it as the input to the feedback circuit 630.

In FIG. 2, the detection circuit 110 is coupled to the second bias circuit 500 and the feedback circuit 130 is coupled to the first bias circuit 400, whereas in FIG. 5, the detection circuit 610 is coupled to the first bias circuit 400 and the feedback circuit 630 is coupled to the second bias circuit 500. The detailed configurations of the detection circuit 610, the inverting circuit 620, and the feedback circuit 630 of FIG. 5 are the same as the detailed configuration of the detection circuit 110, the inverting circuit 120, and the feedback circuit 130 of FIG. 2.

In FIG. 5, when the second bias current is limited by the feedback circuit 630, the current flowing in the power stage 300 is limited, thus the damage to the transistors and elements constituting the power stage 300 may be prevented.

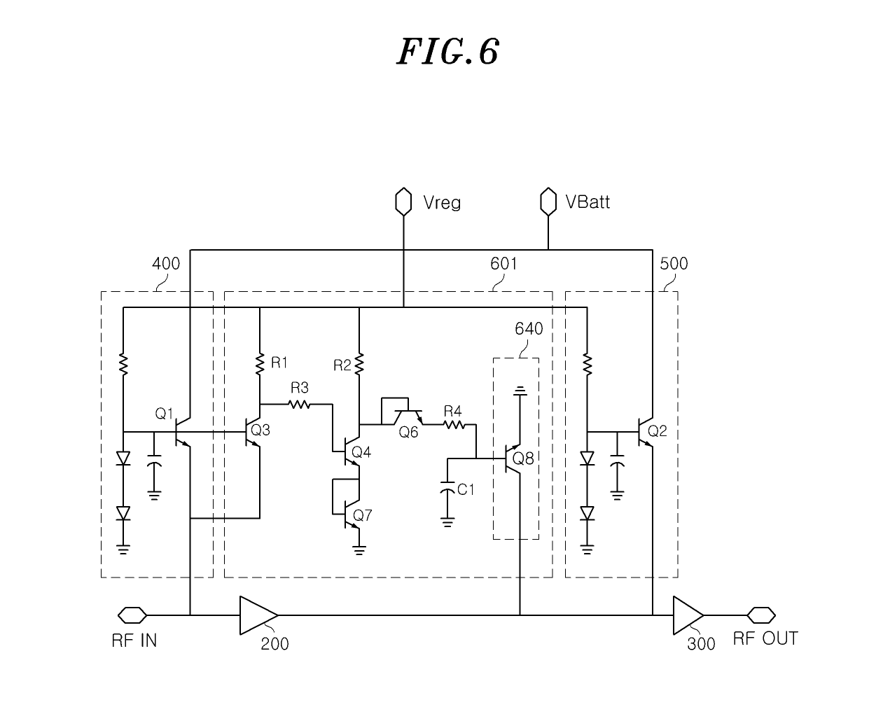

FIG. 6 illustrates a modified example of the protection circuit 600 shown in FIG. 5.

Excluding the feedback circuit 640, the configuration of the protection circuit 601 of FIG. 6 is the same as the configuration of the protection circuit 600 of FIG. 5.

The feedback circuit 640 of the protection circuit 601 of FIG. 6 comprises an eighth transistor Q8. The base of the eighth transistor Q8 is coupled to the collector of the fourth transistor Q4, the collector of the eighth transistor Q8 is coupled to the output of the driver stage 200 (i.e., the input of the power stage 300), and the emitter of the eighth transistor Q8 is coupled to ground. Meanwhile, the base of the eighth transistor Q8 may be coupled to ground via a capacitor C1.

As described above, under low impedance mismatch conditions, an overcurrent flows in the first bias circuit 400 and/or the second bias circuit 500, thus the voltage level at the collector of the fourth transistor Q4 increases. When the voltage level at the collector of the fourth transistor Q4 increases, the eighth transistor Q8 is activated. Also, when the eighth transistor Q8 is activated, impedance seen at the output terminal of the driver stage 200 is changed, and using this change, it is possible to limit the current flowing in the radio frequency power amplifier circuit.

The protection circuit of the present representative embodiments prevents an excessive current flowing in the radio frequency power amplifier circuit under low impedance mismatch conditions. Particularly, the power stage of the radio frequency power amplifier circuit may often fails, but the protection circuit of the present representative embodiments may effectively limit the current flowing in the power stage.

Meanwhile, because the protection circuit of the present representative embodiments may be simply implemented without using complicated elements such as an operational amplifier, a temperature sensor, and a digital-to-analog converter (DAC), cost may be reduced and a smaller sized radio frequency device may be provided.

Also, because the protection circuit of the present representative embodiments is coupled between the first bias circuit of the driver stage and the second bias circuit of the power stage rather than directly coupled to the driver stage and the power stage, the protection circuit does not degrade the radio frequency power amplifier performance on a 50-ohm load, compared to the case in which the protection circuit is directly coupled to the radio frequency power amplifier circuit.

In view of this disclosure, it is to be noted that the protection circuit can be implemented in a variety of elements and variant structures. Further, the various elements, structures and parameters are included for purposes of illustrative explanation only and not in any limiting sense. In view of this disclosure, those skilled in the art may be able to implement the present teachings in determining their own applications and needed elements and equipment to implement these applications, while remaining within the scope of the appended claims.

What is claimed is:

1. A radio frequency device, comprising:
a radio frequency (RF) power amplifier (PA) comprising a driver stage configured to amplify an input signal to generate an output signal and a power stage configured to amplify the output signal;
a first bias circuit configured to supply a first bias current to the driver stage;
a second bias circuit configured to supply a second bias current to the power stage; and
a protection circuit configured to limit a current flowing in the RF PA, the protection circuit being coupled between the first bias circuit and the second bias circuit.

2. The radio frequency device of claim 1, wherein the protection circuit comprises:
a detection circuit configured to detect the second bias current; and
a feedback circuit configured to limit the first bias current when the second bias current detected by the detection circuit is equal to or greater than a threshold current value.

3. The radio frequency device of claim 2, wherein the protection circuit further comprises an inverting circuit coupled between the detection circuit and the feedback circuit, the inverting circuit configured to invert an output of the detection circuit and supply the inverted output as an input to the feedback circuit.

4. The radio frequency device of claim 3, the first bias circuit comprising a first transistor, wherein an emitter current of the first transistor is supplied to the driver stage as the first bias current; and the second bias circuit comprising a second transistor, wherein an emitter current of the second transistor is supplied to the power stage as the second bias current.

5. The radio frequency device of claim 4, wherein the detection circuit comprises:
a third transistor configured to operate as a current mirror circuit of the second transistor; and
a first detection resistor configured to detect a voltage at a collector of the third transistor.

6. The radio frequency device of claim 5, wherein a base of the third transistor is coupled to a base of the second transistor and an emitter of the third transistor is coupled to an emitter of the second transistor, and
the first detection resistor is disposed between a power source and the collector of the third transistor.

7. The radio frequency device of claim 6, the inverting circuit comprising:
a fourth transistor; and
a second detection resistor configured to detect a voltage at a collector of the fourth transistor,
wherein a base of the fourth transistor is coupled to the collector of the third transistor, and the second detection resistor is disposed between the power source and the collector of the fourth transistor.

8. The radio frequency device of claim 7, the feedback circuit comprising:
a fifth transistor, wherein a base of the fifth transistor is coupled to the collector of the fourth transistor, and
a collector of the fifth transistor is coupled to a base of the first transistor.

9. The radio frequency device of claim 7, the feedback circuit comprising:
a fifth transistor, wherein a base of the fifth transistor is coupled to the collector of the fourth transistor, and a collector of the fifth transistor is coupled to an output of the driver stage.

10. The radio frequency device of claim 8, wherein the protection circuit further comprises a voltage level shifter configured to shift a voltage input to the feedback circuit.

11. The radio frequency device of claim 10, wherein the voltage level shifter comprises:
a first shift resistor disposed between the collector of the third transistor and the base of the fourth transistor; and
a sixth transistor and a second shift resistor, the shift register being disposed between the collector of the fourth transistor and the base of the fifth transistor, the sixth transistor and the second shift resistor being connected in series.

12. The radio frequency device of claim 1, wherein the protection circuit comprises:
a detection circuit configured to detect the first bias current; and
a feedback circuit configured to limit the second bias current when the first bias current detected by the detection circuit is equal to or greater than a threshold current value.

13. The radio frequency device of claim 12, wherein the protection circuit further comprises an inverting circuit coupled between the detection circuit and the feedback circuit, the inverting circuit being configured to invert an output of the detection circuit and supply the inverted output as an input to the feedback circuit.

14. A protection circuit for a radio frequency power amplifier, the radio frequency power amplifier comprising: a driver stage configured to amplify an input signal to generate an output signal; a power stage configured to amplify the output signal of the driver stage; a first bias circuit configured to supply a first bias current to the driver stage; and a second bias circuit configured to supply a second bias current to the power stage, the protection circuit comprising:
a detection circuit configured to detect one of the first bias current and the second bias current; and
a feedback circuit which is activated when the current detected by the detection circuit is equal to or greater than a threshold current value, wherein the protection circuit is coupled between the first bias circuit and the second bias circuit.

15. The protection circuit of claim 14, wherein when the current detected by the detection circuit from one of the first bias current circuit or the second bias current circuit is equal to or greater than the threshold current value, the feedback circuit limits the other one of the first bias current or the second bias current.

16. The protection circuit of claim 14, further comprising an inverting circuit coupled between the detection circuit and the feedback circuit, the inverting circuit configured to invert an output of the detection circuit and supply the inverted output as an input to the feedback circuit.

17. A bias device for a radio frequency (RF) power amplifier (PA), the RF PA including a driver stage configured to amplify an input signal to generate an output signal and a power stage configured to amplify the output signal of the driver stage, the bias device comprising:
a first bias circuit configured to supply a first bias current to the driver stage;
a second bias circuit configured to supply a second bias current to the power stage; and
a protection circuit configured to limit a current flowing in the RF PA, wherein the protection circuit is coupled between the first bias circuit and the second bias circuit.

18. The bias device of claim 17, wherein the protection circuit comprises:
a detection circuit configured to detect the second bias current; and
a feedback circuit configured to limit the first bias current when the second bias current detected by the detection circuit is equal to or greater than a threshold current value.

19. The bias device of claim 17, wherein the protection circuit comprises:
a detection circuit configured to detect the first bias current; and
a feedback circuit configured to limit the second bias current when the first bias current detected by the detection circuit is equal to or greater than a threshold current value.

20. The bias device of claim 18, wherein when the current detected by the detection circuit from one of the first bias current circuit or the second bias current circuit is equal to or greater than the threshold current value, the feedback circuit limits the other one of the first bias current or the second bias current.
